(19) United States
(12) Patent Application Publication
(10) Pub. No.: US 2022/0098530 A1
(43) Pub. Date: Mar. 31, 2022

(54) EFFICIENT POST-CMP DEFECT REDUCTION USING CLEANERS CONTAINING OXIDIZING AGENTS

(71) Applicant: FUJIMI INCORPORATED, Kiyosu-shi (JP)

(72) Inventors: Brandon Crockett, Tualatin, OR (US); Jimmy Granstrom, Tualatin, OR (US)

(73) Assignee: FUJIMI INCORPORATED, Kiyosu-shi (JP)

(21) Appl. No.: 17/479,624

(22) Filed: Sep. 20, 2021

Related U.S. Application Data
(60) Provisional application No. 63/083,343, filed on Sep. 25, 2020.

(51) Int. Cl. C11D 11/00; C11D 3/04; C11D 3/39; C11D 3/36; C11D 3/30; C11D 1/06; H01L 21/02

(52) U.S. Cl. CPC C11D 11/0047; C11D 3/048; C11D 3/3947; H01L 21/02057; C11D 3/361; C11D 3/30; C11D 1/06; C11D 3/3942

(57) ABSTRACT

The present technology generally relates to liquid compositions for cleaning post-CMP semiconductor surfaces, and methods of cleaning a semiconductor surface having ceria (CeO₂) particles thereon.

### CROSS-REFERENCE TO RELATED APPLICATIONS

This application claims priority to U.S. Provisional Patent Application No. 63/083,343, filed Sep. 25, 2020, the contents of which are incorporated herein by reference in their entirety.

### TECHNICAL FIELD

The present technology generally relates to liquid compositions for cleaning post-CMP semiconductor surfaces, and methods of cleaning a semiconductor surface having ceria (CeO₂) particles thereon.

### BACKGROUND

Shallow trench isolation (STI) processes are required for the fabrication of semiconductor device nodes. STI chemical mechanical polishing (CMP) processes require a combination of high SiO₂ removal rate, high SiO₂:Si₃N₄ selectivity, and low surface defects. Generally, CeO₂ particles employed in CMP yield the best combination of high SiO₂ removal rate and high SiO₂:Si₃N₄ selectivity. However, CeO₂ CMP tends to yield wafers with high defect counts, primarily consisting of residual CeO₂ particles. Post-CMP cleaning of CeO₂ polished wafers thus presents a major technical problem. Effective, and low cost post-CMP cleaning chemistries for CeO₂ are required to enable STI technology.

Commodity-based cleaning approaches for post-CeO₂ CMP typically utilize harsh chemical conditions such as SC1 (5 parts H₂O, 1 part NH₄OH, 1 part H₂O₂), dilute hydrofluoric acid (DHF), or SPM (1 part H₂SO₄, 4 parts H₂O₂). These approaches are effective at reducing post-CMP CeO₂ defects, but are not without significant drawbacks: SCI leaves significant waste residue on the wafer surface, DHF can lead to unacceptable high material loss, and SPM burdens with cost inefficiencies associated with longer process times and additional infrastructure expenditures.

It is against this background that a need arose to develop the embodiments described herein.

### SUMMARY OF THE DISCLOSURE

Provided herein are compositions and methods for cleaning post-CMP semiconductor surfaces and semiconductor surfaces having CeO₂ particles thereon.

Certain embodiments include a liquid composition for cleaning post-CMP semiconductor surfaces comprising: an oxidizer composition, where the oxidizer composition has a standard reduction potential (E°)>2.0V; and at least one of a basic amine compound and a surfactant. In some embodiments, the liquid composition further comprises an acid. In some embodiments, the acid is selected from a phosphonic acid and bisphosphonic acid In some embodiments, the acid is selected from 1-hydroxyethylidene-1,1-diphosphonic acid, NTMP (Nitrilotris (Methylene Phosphonic Acid)), PBTC (Phosphonobutane Tricarboxylic Acid), EDTMP (Ethylene Diamine Tetra(Methylene Phosphonic Acid)), pyrophosphoric acid, aminoethylene phosphonic acid, medronic acid, and (2-carboxyethylidene)bisphosphonic acid. In some embodiments, the composition comprises a surfactant and a base. In some embodiments, the surfactant is a carboxylic acid surfactant. In some embodiments, the surfactant is selected from capryleth-9 carboxylic acid or another polyoxyethylene alkyl ether carboxylic acid known in the art as suitable for use as a surfactant. In some embodiments, the basic amine compound is an alkylated amine. In some embodiments, the basic amine compound is at least one selected from the group consisting of: 3-amino-4-octanol, 2-(diethylamino) ethanethiol, captamine, diethylethanolamine, methylcysteamine, 2-(tert-butylamino) ethanethiol, 2,2′-dimethoxy-1,1-dimethyl-dimethylamine, 3-butoxypropylamine, N-acetylcysteamine, homocysteamine, N, N-dimethylhydroxylamine, 2-(isopropylamino) ethanol, 2-(methylthioethyl) amine, 1-aminopropane-2-thiol, leucinol, cysteamine, N, O-dimethylhydroxylamine, aminomethyl propanol, aminomethyl propanediol, aminoethyl propanediaol, 2-amino-2-(hydroxymethyl)propane-1,2-diol, 2-dimethylamino-2-methyl-1-propanol, dimethyl 2-amino-2-methyl-1,3-propanediol, dimethyl 2-amino-2-ethyl-1,3-propanediol, tris(hydroxymethyl)(dimethylamino)methane, and 2-Amino-1-butanol. In some embodiments, the oxidizer composition has a standard reduction potential (E°)>2.5V. In some embodiments, the oxidizer composition comprises at least two different oxidizing compounds. In some embodiments, the at least two different oxidizing compounds include persulfate and hydrogen peroxide. In some embodiments, the persulfate is selected from ammonium persulfate, sodium persulfate, potassium persulfate, calcium persulfate, and magnesium persulfate. In some embodiments, the composition has a pH of 2 to 6. In some embodiments, the oxidizer composition is less than 5 wt. % of the liquid composition for cleaning post-CMP semiconductor surfaces. In some embodiments, the liquid composition for cleaning post-CMP semiconductor surfaces comprises a water concentration of at least 95 wt. %.

Other embodiments include a method of cleaning a semiconductor surface having CeO₂ particles thereon, the method comprising applying a liquid composition of any one of the preceding embodiments. Other embodiments include a method of cleaning a semiconductor surface having CeO₂ particles thereon, the method comprising applying a liquid composition comprising an oxidizer composition, where the oxidizer composition has a standard reduction potential (F)>2.0V. In some embodiments, the semiconductor surface having CeO₂ particles was previously subjected to chemical mechanical polishing. In some embodiments, the semiconductor surface comprises TEOS.

### BRIEF DESCRIPTION OF THE DRAWINGS

FIG. 1 shows a post-clean TEOS SP1 defect count versus standard reduction potential of the oxidizer additives for certain embodiments of this disclosure.

### DETAILED DESCRIPTION

Provided herein are compositions and related methods and systems for cleaning post-CMP semiconductor surfaces and semiconductor surfaces having CeO₂ particles thereon. As used herein, the term “chemical mechanical polishing” or “planarization” refers to a process of planarizing (polishing) a surface with the combination of surface chemical reaction and mechanical abrasion. In some embodiments, the chemical reaction is initiated by applying to the surface a composition (interchangeably referred to as a ‘polishing slurry,’ a ‘polishing composition,’ a ‘slurry composition’ or simply a ‘slurry’) capable of reacting with a surface material, thereby turning the surface material into a product that can be more easily removed by simultaneous mechanical abrasion. In some embodiments, the mechanical abrasion is performed by contacting a polishing pad with the surface, and moving the polishing pad relative to the surface.

### Composition

The liquid compositions for cleaning post-CMP semiconductor surfaces can comprise, consist essentially of, or consist of the following components.

The composition can comprise an oxidizer composition and at least one of a basic amine compound and a surfactant. In some embodiments, the composition also comprises an acid. In some embodiments, the composition also comprises water, such as DI water.

Oxidizer

The composition can comprise an oxidizer composition. In some embodiments, the oxidizer composition has a standard reduction potential (E°)>2.0V (e.g., >2.1V, >2.2V, >2.3V, >2.4V, >2.5V, >2.6V, >2.7V, >2.8V, >2.9V, or >3.0V). In some embodiments, the oxidizer composition has a standard reduction potential (E°) less than 4V, or less than 3.5V, or less than 3V. In some embodiments, the oxidizer composition comprises at least two different oxidizing compounds. For example, in some embodiments, the at least two different oxidizing compounds include persulfate and a peroxide. The persulfate is not particularly limited, and includes, e.g., ammonium persulfate, sodium persulfate, potassium persulfate, calcium persulfate, and magnesium persulfate. In some embodiments, the peroxide is hydrogen peroxide.

The oxidizer composition can comprise about 0.05 to about 4 wt. % of the composition. In some embodiments, the persulfate oxidizer can comprise about 0.05 to about 0.2 wt. % of the composition (e.g., 0.05, 0.06, 0.07, 0.08, 0.09, 0.1, 0.11, 0.12, 0.13, 0.14, 0.15, 0.16, 0.17, 0.18, 0.19 or 0.2 wt. %). In some embodiments, the peroxide oxidizer can comprise about 0 to about 4 wt. % of the composition. In some embodiments, the peroxide oxidizer is only added at the point of use. It will be understood by those in the art that these concentrations are at the point of use, and the composition may include a higher weight percentage of oxidizer if formulated in a concentrated composition prior to use.

Basic Amine Compound

The composition can comprise one or more basic amine compound. In some embodiments, the basic amine compound is an alkylated amine. The basic amine compound is not particularly limited, and includes, e.g., at least one selected from: 3-amino-4-octanol, 2-(diethylamino) ethanethiol, captamine, diethylethanolamine, methylcysteamine, 2-(tert-butylamino) ethanethiol, 2,2′-dimethoxy-1,1-dimethyl-dimethylamine, 3-butoxypropylamine, N-acetylcysteamine, homocysteamine, N, N-dimethylhydroxylamine, 2-(isopropylamino) ethanol, 2-(methylthioethyl) amine, 1-aminopropane-2-thiol, leucinol, cysteamine, N, O-dimethylhydroxylamine, aminomethyl propanol, aminomethyl propanediol, aminoethyl propanediaol, 2-amino-2-(hydroxymethyl)propane-1,2-diol, 2-dimethylamino-2-methyl-1-propanol, dimethyl 2-amino-2-methyl-1,3-propanediol, dimethyl 2-amino-2-ethyl-1,3-propanediol, tris(hydroxymethyl)(dimethylamino)methane, and 2-Amino-1-butanol.

The basic amine compound can comprise about 0.05 to about 0.2 wt. % of the composition (e.g., 0.05, 0.06, 0.07, 0.08, 0.09, 0.1, 0.11, 0.12, 0.13, 0.14, 0.15, 0.16, 0.17, 0.18, 0.19 or 0.2 wt. %). It will be understood by those in the art that these concentrations are at the point of use, and the composition may include a higher weight percentage of basic amine compound if formulated in a concentrated composition prior to use.

Surfactant

The composition can comprise one or more surfactant. In some embodiments, the surfactant is a carboxylic acid surfactant. The surfactant is not particularly limited, and includes, e.g., capryleth-9 carboxylic acid or another polyoxyethylene alkyl ether carboxylic acid known in the art as suitable for use as a surfactant.

The surfactant can comprise about 0 to about 0.02 wt. % of the composition (e.g., 0.001, 0.002, 0.003, 0.004, 0.005, 0.006, 0.007, 0.008, 0.009, 0.01, 0.011, 0.012, 0.013, 0.014, 0.015, 0.016, 0.017, 0.018, 0.019 or 0.02 wt. %). It will be understood by those in the art that these concentrations are at the point of use, and the composition may include a higher weight percentage of surfactant if formulated in a concentrated composition prior to use.

Acid

The composition can comprise one or more acid. In some embodiments, the acid is a phosphonic acid or bisphosphonic acid. For example, in some embodiments, the acid is selected from 1-hydroxyethylidene-1,1-diphosphonic acid, NTMP (Nitrilotris (Methylene Phosphonic Acid)), PBTC (Phosphonobutane Tricarboxylic Acid), EDTMP (Ethylene Diamine Tetra(Methylene Phosphonic Acid)), pyrophosphoric acid, aminoethylene phosphonic acid, medronic acid, and (2-carboxyethylidene)bisphosphonic acid.

The acid can comprise about 0 to about 0.2 wt. % of the composition (e.g., 0.01, 0.02, 0.03, 0.04, 0.05, 0.06, 0.07, 0.08, 0.09, 0.1, 0.11, 0.12, 0.13, 0.14, 0.15, 0.16, 0.17, 0.18, 0.19 or 0.2 wt. %). It will be understood by those in the art that these concentrations are at the point of use, and the composition may include a higher weight percentage of acid if formulated in a concentrated composition prior to use.

Additional Components/Aspects

In some embodiments, the composition also comprises water, such as DI water. The water may be present in an amount of greater than 90 wt. %, e.g., 91, 92, 93, 94, 95, 96, 97, 98 or 99 wt. %.

The pH of the composition is generally a value of from about 2 to about 6 (e.g., about 2, 3, 4, or 5). Appropriate pH adjusters and/or buffers may be included in the composition to adjust pH.

### Methods

In another aspect of the present disclosure, provided herein are methods for cleaning a surface having ceria particles comprising contacting the surface with a composition of the present disclosure. In some embodiments, the surface is a semiconductor surface that comprises TEOS. In some embodiments, the surface having ceria particles was previously subjected to chemical mechanical polishing (CMP). In some embodiments, the method of cleaning is performed in a unit that is separate from a polishing area comprising platens. In some embodiments, the unit is a brush box. In some embodiments, the method of cleaning is performed without a prior on-platen CMP rinse. In some embodiments, the method of cleaning is performed by contacting the surface with a composition of the present disclosure that does not include abrasives. In some embodiments, the method of cleaning further comprises a subsequent wash step with, e.g., water.

In another aspect of the present disclosure, provided herein are methods for rinsing a surface having ceria particles comprising contacting the surface with a composition of the present disclosure. In some embodiments, the surface is a semiconductor surface that comprises TEOS. In some embodiments, the surface having ceria particles was previously subjected to chemical mechanical polishing (CMP). In some embodiments, the method of rinsing a surface is performed on a platen after polishing or performed on a subsequent platen. In some embodiments, the platen is a different platen from a platen used for CMP. In some embodiments, the method of rinsing is performed by contacting the surface with a composition of the present disclosure that does not include abrasives, or a composition of the present disclosure that includes an amount of abrasives that is less than a polishing composition for CMP. In some embodiments, the method of rinsing is performed without a subsequent cleaning step.

In another aspect of the present disclosure, provided herein are methods of rinsing and cleaning a surface having ceria particles comprising conducting a method of rinsing as disclosed herein followed by a method of cleaning as disclosed herein. In some embodiments, the combined methods of rinsing and cleaning allow for a reduced time needed for the surface having ceria particles to be cleaned compared to a surface having ceria particles that was not subjected to the rinsing process.

### EXAMPLES

### Example 1

In order to test ceria removal performance, cleaning compositions were formulated with the following materials listed in Table 1. All cleaners were formulated at pH 3.3+/−0.3 at PoU, some variation in pH was allowed as additional pH adjusters were not added to the formulations. The oxidizing agents (except for H₂O₂) were used in equimolar amounts; in the case of H₂O₂, the oxidizer was used at 3 wt-% as H₂O₂ was added at PoU. Defect counts were generated on 200 mm TEOS BTWs in one brush box. Polishing condition: Ebara, 200 mm, IC1010, 1.4 psi, 100/95 rpm, 200 mi/min, 30 seconds rinse at 1000 mi/min (BB cleaning).

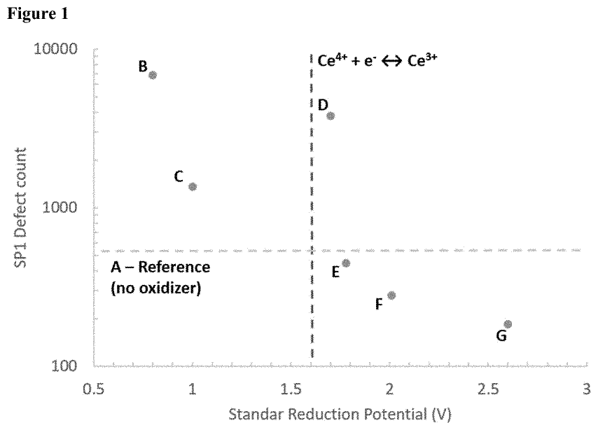

TABLE 1
Cleaners used in the study, the cleaner compositions, as well as the SP1 defect counts obtained from each cleaner.

| Cleaner denotation in FIG. 1 | | A | B | C | D | E | F | G |
|---|---|---|---|---|---|---|---|---|
| Oxidizing agent(s) | | — | KNO₃ | NH₄VO₃ | KMNO₄ | H₂O₂ | NH₄S₂O₈ | NH₄S₂O₈ + H₂O₂ |
| TEOS defect count (—) | | 552 | 6850 | 1355 | 3779 | 446 | 280 | 184 |
| Component | 1-hydroxyethylidene-1,1-diphosphonic | 0.0666 | 0.0666 | 0.0666 | 0.0666 | 0.0666 | 0.0666 | 0.0666 |
| Concentration | acid (HEDP) | | | | | | | |
| (wt-%) at PoU | 3-amino-4-octanol (O amino alcohol) | 0.0828 | 0.0828 | 0.0828 | 0.0828 | 0.0828 | 0.0828 | 0.0828 |
| | Capryleth-9 carboxylic acid (Akypo LF2) | 0.0079 | 0.0079 | 0.0079 | 0.0079 | 0.0079 | 0.0079 | 0.0079 |
| | Oxidizing agents (other than H₂O₂) | — | 0.0544 | 0.063 | 0.0851 | — | 0.1228 | 0.1228 |
| | H₂O₂ (added at PoU) | — | — | — | — | 3 | — | 3 |
| | DI water | Remainder | Remainder | Remainder | Remainder | Remainder | Remainder | Remainder |
| | Total | 100 | 100 | 100 | 100 | 100 | 100 | 100 |

The compositions above were used for conditioning post-polishing under the following parameters listed in Table 2.

TABLE 2
P1 polishing conditions for Ceria CMP.

| | |
|---|---|
| Polisher | APPLIED MATERIALS REFLEXION LK |

| CATEGORY | PARAMETER | PLATEN 2 | |
|---|---|---|---|
| | Slurry | HC60 300x dilution | |
| | Polishing Head | Profiler (3zone) | |
| | Polishing Pad | IC1010 | |
| Polishing | Platen speed | 100 | rpm |
| parameters | Head speed | 95 | rpm |
| | Retaining Ring | 5.7 | psi |
| | Zone 1 | 3.7 | psi |
| | Zone 2 | 1.4 | psi |
| | Zone 3 | 1.4 | psi |
| | Head sweep | None/Fixed | |
| | Slurry Flow Rate | 200 | ml/min |
| | TSDA | 0.75 | |
| | Polishing Time for BTW | 60 | sec |
| Conditioning | Conditioning mode | Ex Situ | |
| parameters | Conditioner | 3M A165 | |
| | Conditioning sweep | 12.0 | swps/min |
| | Down force | 5.0 | lbf |
| | Disk speed | 90 | rpm |
| | Platen speed | 103 | rpm |
| | Conditioning time | 20.0 | sec |

FIG. 1 shows the post-clean TEOS SP1 defect count versus standard reduction potential of the oxidizer additive were measured from SP1. Reduction potential is reported as the Standard Reduction Potential, taken as E°. The standard reduction potential for Ce⁴⁺ is shown as a dotted vertical red line. Defect counts for the reference cleaner A with no oxidizer added are shown as a dotted horizontal grey line (cleaner D).

The results plotted in FIG. 1 highlight a clear, inverse correlation between the oxidizer additive E°, and the post-clean SP1 defect counts. Cleaner formulation D deviates from the trend. Formulation D utilizes KMnO₄ as the oxidizing agent, which under acidic conditions may precipitate MnO₂₍ₛ₎ as noted in Table 2. Even though the standard reduction potential of KMnO₄ is above 1.61 V, the precipitate solids contribute to the high SP1 Defect counts.

Comparison of “E”, “F” and “G” clearly show a synergistic reduction of TEOS defect count by combining NH₄S₂O₈ and H₂O₂ (“G” compared with “E” and “F”). The synergistic effect may be explained by the generation of sulfate radicals from H₂O₂ activation of persulfate. This approach is significantly different from piranha etching (H₂SO₄+H₂O₂+A) as no acids are used, the approach can be applied under mild acidic conditions (pH>3), and sulfate radicals can be generated close to room temperature.

### EQUIVALENTS

The present technology is not to be limited in terms of the particular embodiments described in this application, which are intended as single illustrations of individual aspects of the present technology. Many modifications and variations of this present technology can be made without departing from its spirit and scope, as will be apparent to those skilled in the art. Functionally equivalent methods and apparatuses within the scope of the present technology, in addition to those enumerated herein, will be apparent to those skilled in the art from the foregoing descriptions. Such modifications and variations are intended to fall within the scope of the present technology. It is to be understood that this present technology is not limited to particular methods, reagents, compounds compositions, or biological systems, which can, of course, vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member.

All numerical designations, e.g., pH, temperature, time, concentration, amounts, and molecular weight, including ranges, are approximations which are varied (+) or (−) by 10%, 1%, or 0.1%, as appropriate. It is to be understood, although not always explicitly stated, that all numerical designations may be preceded by the term “about.” As used herein, the term “about” will be understood by persons of ordinary skill in the art and will vary to some extent depending upon the context in which it is used. If there are uses of the term which are not clear to persons of ordinary skill in the art given the context in which it is used, “about” will mean up to plus or minus 10% of the particular term. It is also to be understood, although not always explicitly stated, that the reagents described herein are merely exemplary and that equivalents of such are known in the art.

All patents, patent applications, provisional applications, and publications referred to or cited herein are incorporated by reference in their entirety, including all tables, to the extent they are not inconsistent with the explicit teachings of this specification.

Other embodiments are set forth in the following claims.

1. A liquid composition for cleaning post-CMP semiconductor surfaces comprising:
an oxidizer composition, where the oxidizer composition has a standard reduction potential (E°)>2.0V; and
at least one of a basic amine compound and a surfactant.

2. The liquid composition of claim 1 further comprising an acid.

3. The liquid composition of claim 2, wherein the acid is selected from a phosphonic acid and bisphosphonic acid

4. The liquid composition of claim 3, wherein the acid is selected from 1-hydroxyethylidene-1,1-diphosphonic acid, NTMP (Nitrilotris (Methylene Phosphonic Acid)), PBTC (Phosphonobutane Tricarboxylic Acid), EDTMP (Ethylene Diamine Tetra(Methylene Phosphonic Acid)), pyrophosphoric acid, aminoethylene phosphonic acid, medronic acid, and (2-carboxyethylidene)bisphosphonic acid.

5. The liquid composition of claim 1 comprising a surfactant and a base.

6. The liquid composition of n m claim 1, wherein the surfactant is a carboxylic acid surfactant.

7. The liquid composition of claim 1, wherein the surfactant is selected from capryleth-9 carboxylic acid or another polyoxyethylene alkyl ether carboxylic acid known in the art as suitable for use as a surfactant.

8. The liquid composition of claim 1, wherein the basic amine compound is an alkylated amine.

9. The liquid composition of claim 1, wherein the basic amine compound is at least one selected from the group consisting of: 3-amino-4-octanol, 2-(diethylamino) ethanethiol, captamine, diethylethanolamine, methylcysteamine, 2-(tert-butylamino) ethanethiol, 2,2′-dimethoxy-1,1-dimethyl-dimethylamine, 3-butoxypropylamine, N-acetylcysteamine, homocysteamine, N, N-dimethylhydroxylamine, 2-(isopropylamino) ethanol, 2-(methylthioethyl) amine, 1-aminopropane-2-thiol, leucinol, cysteamine, N, O-dimethylhydroxylamine, aminomethyl propanol, aminomethyl propanediol, aminoethyl propanediaol, 2-amino-2-(hydroxymethyl)propane-1,2-diol, 2-dimethylamino-2-methyl-1-propanol, dimethyl 2-amino-2-methyl-1,3-propanediol, dimethyl 2-amino-2-ethyl-1,3-propanediol, tris(hydroxymethyl)(dimethylamino)methane, and 2-Amino-1-butanol.

10. The liquid composition of claim 1, wherein the oxidizer composition has a standard reduction potential (E°)>2.5V.

11. The liquid composition of claim 1, wherein the oxidizer composition comprises at least two different oxidizing compounds.

12. The liquid composition of claim 11, wherein the at least two different oxidizing compounds include persulfate and hydrogen peroxide.

13. The liquid composition of claim 12, wherein the persulfate is selected from ammonium persulfate, sodium persulfate, potassium persulfate, calcium persulfate, and magnesium persulfate.

14. The liquid composition of claim 1, wherein the composition has a pH of 2 to 6.

15. The liquid composition of claim 1, wherein the oxidizer composition is less than 5 wt. % of the liquid composition for cleaning post-CMP semiconductor surfaces.

16. The liquid composition of claim 1, wherein the liquid composition for cleaning post-CMP semiconductor surfaces has a water concentration of at least 95 wt. %.

17. A method of cleaning a semiconductor surface having CeO₂ particles thereon, the method comprising applying a liquid composition of claim 1.

18. A method of cleaning a semiconductor surface having CeO₂ particles thereon, the method comprising applying a liquid composition comprising an oxidizer composition, where the oxidizer composition has a standard reduction potential (E°)>2.0V.

19. The method of claim 17, wherein the semiconductor surface having CeO₂ particles was previously subjected to chemical mechanical polishing.

20. The method of claim 17, wherein the semiconductor surface comprises TEOS.
